(19) United States
(12) Patent Application Publication
(10) Pub. No.: US 2025/0261539 A1
(43) Pub. Date: Aug. 14, 2025

(54) DISPLAY DEVICE

(71) Applicant: LG Display Co., Ltd., Seoul (KR)

(72) Inventors: SungGyu KIM, Paju-si (KR); HyoYoung JUN, Seoul (KR); Jeongmin PARK, Paju-si (KR)

(73) Assignee: LG Display Co., Ltd., Seoul (KR)

(21) Appl. No.: 18/890,316

(22) Filed: Sep. 19, 2024

(30) Foreign Application Priority Data
Feb. 8, 2024 (KR) 10-2024-0019762

(51) Int. Cl. H10K 59/80; H10K 59/65

(52) U.S. Cl. CPC H10K 59/871; H10K 59/65

(57) ABSTRACT

A display device in one example includes a display panel having a display area and a non-display area configured to surround the display area, a backplate disposed below the display panel, a first bonding layer disposed between the display panel and the backplate, a metal plate disposed on a rear surface of the backplate, and a second bonding layer disposed between the backplate and the metal plate. An edge of the backplate or an edge of the metal plate has a smaller volume than a central portion of the backplate or a central portion of the metal plate. Therefore, it is possible to minimize a deformation of the display panel by reducing or mitigating stress to be applied to the display panel in a reliability evaluation environment.

### CROSS-REFERENCE TO RELATED APPLICATIONS

This application claims priority to Korean Patent Application No. 10-2024-0019762 filed on Feb. 8, 2024, in the Korean Intellectual Property Office, the entire contents of which is hereby expressly incorporated by reference into the present application.

### BACKGROUND

### Field

The present disclosure relates to a display device, and more particularly, to a display device capable of reducing or mitigating stress to be applied to a display panel.

### Discussion of the Related Art

Display devices, which visually display electrical information signals, are being rapidly developed in accordance with the progress in the information era. Various studies are being continuously conducted to develop a variety of display devices which are thin and lightweight, consume low power, and have improved performance.

As the representative display devices, there can be a liquid crystal display (LCD) device, a field emission display (FED) device, an electrowetting display (EWD) device, an organic light-emitting display (OLED) device, and the like.

An electroluminescent display device such as an organic light-emitting display device is a display device that autonomously emits light. Unlike a liquid crystal display device, the electroluminescent display device does not require a separate light source and thus can be manufactured as a lightweight, thin display device.

In addition, the electroluminescent display device is advantageous in terms of power consumption because the electroluminescent display device operates at a low voltage. Further, the electroluminescent display device is expected to be adopted in various fields because the electroluminescent display device is also excellent in implementation of colors, response speeds, viewing angles, and contrast ratios (CRs).

### SUMMARY OF THE DISCLOSURE

An object to be achieved by an embodiment of the present disclosure is to provide a display device capable of reducing or preventing stress to be applied to a display panel in a high-temperature and/or high-humidity environment.

An object to be achieved by another embodiment of the present disclosure is to provide a display device capable of minimizing a deformation of a display panel in a high-temperature and/or high-humidity environment.

Another object to be achieved by aspects of the present disclosure is to provide a display device which can address the limitations and disadvantages associated with the related art.

Objects of the present disclosure are not limited to the above-mentioned objects, and other objects, which are not mentioned above, can be clearly understood by those skilled in the art from the following descriptions.

A display device according to an embodiment of the present disclosure includes a display panel including a display area and a non-display area configured to surround the display area, a backplate disposed below the display panel, a first bonding layer disposed between the display panel and the backplate, a metal plate disposed on a rear surface of the backplate, and a second bonding layer disposed between the backplate and the metal plate, in which an edge of the backplate or an edge of the metal plate has a smaller volume than a central portion of the backplate or a central portion of the metal plate.

Other detailed matters of the example embodiments of the present disclosure are included in the detailed description and the drawings.

In the present disclosure, a volume of the edge of the metal plate or the edge of the backplate, which is disposed below the display panel, is smaller than a volume of the central portion of the metal plate or the central portion of the backplate, such that the stress which can be caused by the contraction or expansion of the bonding layer can be guided to the edge of the metal plate or the edge of the backplate.

In the present disclosure, the stress which can be caused by the contraction or expansion of the bonding layer is guided to the edge of the metal plate or the edge of the backplate, such that the stress which can be caused by the contraction or expansion of the bonding layer does not affect the display panel, which can minimize or prevent a deformation of the display panel.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic top plan view of a display device according to an embodiment of the present disclosure;

FIG. 2 is a cross-sectional view taken along line II-II′ in FIG. 1;

FIG. 3 is a cross-sectional view of a subpixel according to the embodiment of the present disclosure;

FIG. 4A is a cross-sectional view taken along line IV-IV′ in FIG. 1;

FIG. 4B is a cross-sectional view of a non-display area of a display device according to another embodiment of the present disclosure;

FIG. 4C is a cross-sectional view of a non-display area of a display device according to still another embodiment of the present disclosure;

FIG. 5A is a cross-sectional view of a non-display area of a display device according to yet another embodiment of the present disclosure;

FIG. 5B is a cross-sectional view of a non-display area of a display device according to still yet another embodiment of the present disclosure; and

FIG. 5C is a cross-sectional view of a non-display area of a display device according to a further embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated. Further, the term “can” fully encompasses all the meanings and coverages of the term “may.”

The features of various embodiments of the present disclosure can be partially or entirely adhered to or combined with each other and can be interlocked and operated in technically various ways, and the embodiments can be carried out independently of or in association with each other.

Hereinafter, various example embodiments of the present disclosure will be described in detail with reference to the accompanying drawings. All the components of each display device according to all embodiments of the present disclosure are operatively coupled and configured.

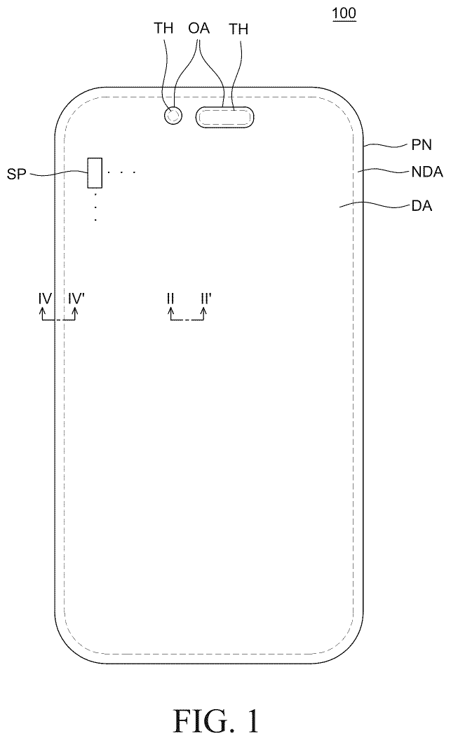

FIG. 1 is a top plan view of a display device according to an embodiment of the present disclosure.

Referring to FIG. 1, a display device 100 includes a display panel PN. The display panel PN can include a display area DA (active area), an optical area OA disposed in the display area DA and including through-holes TH, and a non-display area NDA (non-active area) configured to surround the display area DA. The non-display area NDA can surround the display area DA entirely or only in part(s).

The display area DA is an area of the display panel PN in which images are displayed.

A plurality of subpixels SP and a circuit for operating the plurality of subpixels SP can be disposed in the display area DA. The plurality of subpixels SP can be minimum units that constitute the display area DA. Display elements (e.g., organic light emitting diodes) can be respectively disposed in the plurality of subpixels SP. For example, an organic light-emitting element including an anode, a light-emitting layer, and a cathode can be disposed in each of the plurality of subpixels SP. However, the present disclosure is not limited thereto. In addition, the circuit configured to operate the plurality of subpixels SP can include driving elements, lines, and the like. For example, the circuit can include a thin-film transistor, a storage capacitor, a gate line, a data line, and the like. However, the present disclosure is not limited thereto.

The optical area OA is an area disposed in the display area DA, and the through-holes TH can be disposed in the optical area OA. The through-hole TH can be disposed in the display area DA of the display panel PN, thereby reducing a bezel area, which is the non-display area NDA, and maximizing the display area DA. A design product with the maximized display area DA maximizes a degree of screen immersion of a user, thereby improving an aesthetic appearance.

The through-hole TH can be formed to correspond to an electronic optical device. The electronic optical device can be a device that receives light having passed through the display panel and performs a predetermined function in response to the received light. Therefore, the electronic optical device can be disposed to overlap the through-hole TH of the display panel PN. For example, the electronic optical device can be configured as a camera or various sensors. However, the present disclosure is not limited thereto. The electronic optical device can include all devices that perform predetermined functions in response to the light. Meanwhile, because the electronic optical device is disposed below the display panel PN, the electronic optical device may not be visually recognized by the user. For example, in case that the electronic optical device is a camera, the camera is disposed on the rear surface of the display panel PN. However, the camera can capture an image of the front surface of the display device 100 instead of the rear surface of the display device 100.

FIG. 1 illustrates two through-holes TH. However, the present disclosure is not limited thereto. The number of through-holes TH variously can be provided. For example, one or two holes are disposed in the display area DA. A camera can be disposed in a first hole, and a distance detection sensor, a face recognition sensor, or a wide angle camera can be disposed in a second hole.

The non-display area NDA is an area in which no image is displayed.

The non-display area NDA can be bent, such that the non-display area NDA is not visible from a front surface. The non-display area NDA can be covered by a casing. The non-display area NDA is called a bezel area.

In the example of FIG. 1, the non-display area NDA surrounds the display area DA having a quadrangular shape. However, the shapes and arrangements of the display area DA and the non-display area NDA are not limited to the example illustrated in FIG. 1. For example, the display area DA and the non-display area NDA can be suitable for the design of an electronic device equipped with the display device 100. For example, an example shape of the display area DA can also be a pentagonal shape, a hexagonal shape, a circular shape, an elliptical shape, or the like.

Various lines and circuits for operating the organic light-emitting element in the display area DA can be disposed in the non-display area NDA. For example, the non-display area NDA can include link lines for transmitting signals to the plurality of subpixels and the circuit in the display area DA. The non-display area NDA can include gate-in-panel (GIP) lines or drive ICs such as the gate drive part and the data drive part. However, the present disclosure is not limited thereto.

The display device 100 can further include various additional elements configured to generate various signals or operate a pixel in the display area DA. The additional elements for operating the pixel can include an inverter circuit, a multiplexer, an electrostatic discharge (ESD) circuit, and the like. The display device 100 can also include additional elements related to functions other than the function of operating the pixel. For example, the display device 100 can further include additional elements that provide a touch detection function, a user certification function (e.g., fingerprint recognition), a multi-level pressure detection function, a tactile feedback function, and the like. The above-mentioned additional elements can be positioned in the non-display area NDA and/or an external circuit connected to a connection interface.

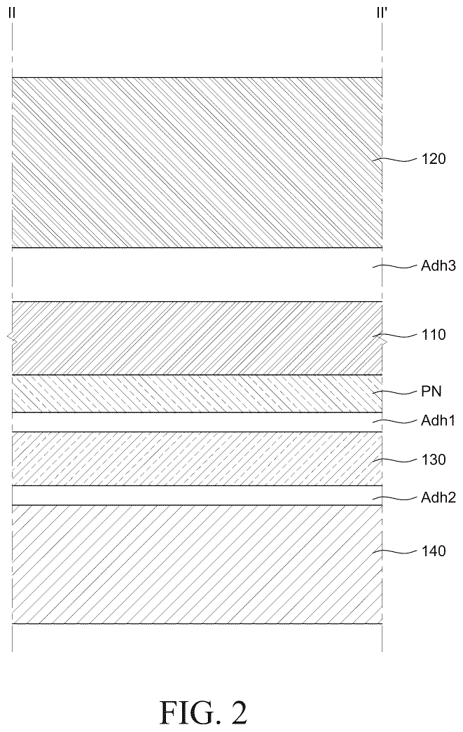

Hereinafter, the constituent elements of the display device 100 will be described in more detail with reference to FIG. 2.

FIG. 2 is a cross-sectional view taken along line II-II′ in FIG. 1.

With reference to FIG. 2, the display device 100 can include a cover member 120, a third bonding layer Adh3, a polarizing layer 110, the display panel PN, a first bonding layer Adh1, a backplate 130, a second bonding layer Adh2, and a metal plate 140.

First, the display panel PN can include a substrate and light-emitting elements.

The substrate can be a support member for supporting other constituent elements disposed on the substrate of the display device 100, and the substrate can be made of an insulating material. For example, the substrate can be made of glass, resin, or the like. In addition, the substrate can include plastic such as polymer or polyimide (PI) and be made of a material having flexibility.

The light-emitting elements can be disposed on the substrate. The light-emitting elements can be differently defined depending on the type of display panel PN. For example, in case that the display panel PN is an organic light-emitting display panel, the light-emitting element can be an organic light-emitting diode (OLED).

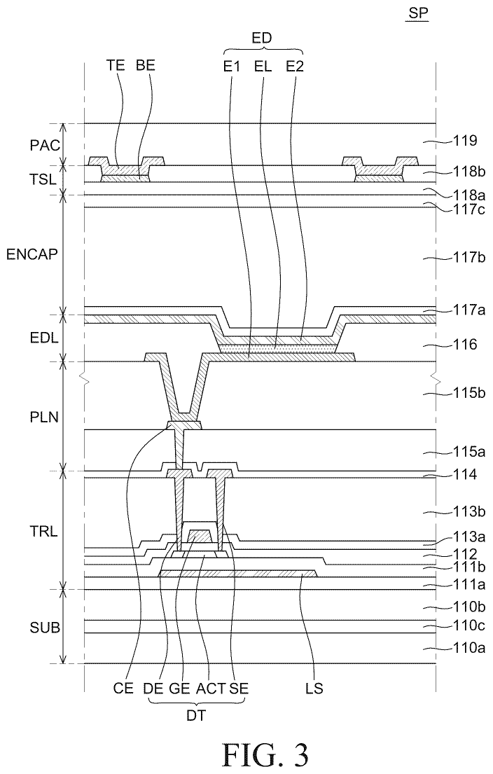

A driving transistor for operating the light-emitting element can be disposed between the substrate and the light-emitting element. The driving transistors can be respectively disposed in a plurality of subpixel areas. For example, the driving transistor can include a gate electrode, an active layer, a source electrode, and a drain electrode. In addition, the driving transistor can further include a gate insulation layer that insulates the gate electrode from the active layer, and the driving transistor can further include an interlayer insulation layer that insulates the gate electrode from the source electrode and the drain electrode. The display panel PN will be described in detail with reference to FIG. 3 to be described below.

The polarizing layer 110 can be disposed above the display panel PN. The polarizing layer 110 can be a layer for polarizing incident light. The polarizing layer 110 can include a polarizing plate that is a film having light transmittance at a predetermined level and absorbs external light and reflected light thereof to suppress a decrease in contrast ratio. For example, it is possible to suppress the deterioration in display quality caused by reflected light made when external light is reflected.

The cover member 120 can be disposed on the polarizing layer 110. The cover member 120 can have a shape corresponding to the display panel PN and be disposed to cover the display panel PN. The cover member 120 can protect the display panel PN from an external impact, moisture, heat, or the like. For example, the cover member 120 can be a tempered glass. However, the present disclosure is not limited thereto.

The third bonding layer Adh3 can be disposed between the polarizing layer 110 and the cover member 120. The third bonding layer Adh3 can fix the polarizing layer 110 and the cover member 120. The third bonding layer Adh3 can minimize the occurrence of foreign substances or bubbles between the polarizing layer 110 and the cover member 120, and an optically transparent bonding agent, such as an optically clear adhesive (OCA) or an optical clear resin (OCR), can be used. However, the present disclosure is not limited thereto.

Meanwhile, the backplate 130 can be disposed below the display panel PN. The backplate 130 can support the display panel PN and protect the display panel PN from external moisture, heat, impact, or the like. The backplate 130 can be made of a transparent organic insulating material to suppress curl and static electricity of the display device 100 and inspect an external appearance of the rear surface of the display device 100. For example, the backplate 130 can be made of a plastic material such as polymethyl methacrylate (PMMA), polycarbonate (PC), polyvinyl alcohol (PVA), acrylonitrile-butadiene-styrene (ABS), polyethylene terephthalate (PET), silicone, and polyurethane (PU). However, the present disclosure is not limited thereto.

A first bonding layer Adh1 can be disposed between the backplate 130 and the display panel PN. The first bonding layer Adh1 can fix the backplate 130 and the display panel PN. The first bonding layer Adh1 can be a pressure sensitive adhesive or an optically transparent bonding agent, such as an optically clear adhesive or an optical clear resin, to minimize the occurrence of foreign substances or bubbles between the backplate 130 and the display panel PN. However, the present disclosure is not limited thereto.

The metal plate 140 can be disposed below the backplate 130. The metal plate 140 can protect the backplate 130 from an external impact that can be applied during the process of manufacturing the display device. In addition, the metal plate 140 can serve as a heat dissipation plate for dissipating heat, which is generated from the display panel PN, to the outside. The metal plate 140 can be made of a metallic material such as stainless steel (SUS), stainless steel (SUS) containing different metals such as nickel (Ni), iron (Fe), aluminum (Al), and magnesium (Mg). Particularly, stainless steel (SUS) can be applied to the metal plate 140. For example, because stainless steel (SUS) has high restoring force and rigidity, the metal plate 140 can maintain high rigidity even though a thickness of the metal plate 140 decreases.

The second bonding layer Adh2 can be disposed between the backplate 130 and the metal plate 140. The second bonding layer Adh2 can fix the backplate 130 and the metal plate 140. The second bonding layer Adh2 can be a pressure sensitive adhesive or an optically transparent bonding agent, such as an optically clear adhesive or an optical clear resin, to minimize the occurrence of foreign substances or bubbles between the backplate 130 and the metal plate 140. However, the present disclosure is not limited thereto.

Hereinafter, the constituent elements of the display panel PN will be described in more detail with reference to FIG. 3.

FIG. 3 is a cross-sectional view illustrating a cross-sectional structure of one subpixel disposed in the display area according to the embodiment of the present disclosure. Specifically, FIG. 3 illustrates the constituent elements included in the display panel in one subpixel disposed in the display area, as an example. Each subpixel of any display device in the present disclosure can have the subpixel configuration of FIG. 3 or any other configuration discussed in the present application.

With reference to FIG. 3, in the subpixel SP disposed in the display area AA, a transistor layer TRL can be disposed above a substrate SUB, and a planarization layer PLN can be disposed above the transistor layer TRL. In addition, a light-emitting element layer EDL can be disposed above the planarization layer PLN, an encapsulation layer ENCAP can be disposed above the light-emitting element layer EDL, a touch sensing layer TSL can be disposed above the encapsulation layer ENCAP, and a protective layer PAC can be disposed above the touch sensing layer TSL. In addition, a polarizing layer POL can be disposed above the protective layer PAC.

The substrate SUB is a component for supporting various constituent elements included in the display device 100 and can be made of an insulating material. The substrate SUB can include a first substrate 110a, a second substrate 110b, and an interlayer insulation layer 110c. The interlayer insulation layer 110c can be disposed between the first substrate 110a and the second substrate 110b. As described above, the substrate SUB can include the first substrate 110a, the second substrate 110b, and the interlayer insulation layer 110c, which can suppress moisture penetration. For example, the first substrate 110a and the second substrate 110b can each be a substrate made of polyimide (PI).

Various types of patterns GE, DE, SE, and ACT for forming a transistor such as the driving transistor DT, various types of insulation layers 111a, 111b, 112, 113a, 113b, and 114, and various types of metal patterns LS can be disposed on the transistor layer TRL in the display area AA.

Hereinafter, a layered structure of the transistor layer TRL will be described in more detail.

A multi-buffer layer 111a can be disposed on the second substrate 110b, and an active buffer layer 111b can be disposed on the multi-buffer layer 111a.

A light-blocking layer LS, which serves as a light shield, can be disposed on the multi-buffer layer 111a.

The active buffer layer 111b can be disposed on the light-blocking layer LS.

An active layer ACT of the driving transistor DT can be disposed on the active buffer layer 111b. For example, the active layer ACT can be made of polysilicon (p-Si), amorphous silicon (a-Si), or oxide semiconductor. However, the present disclosure is not limited thereto.

A gate insulation layer 112 can be disposed on the active layer ACT. The gate insulation layer 112 can be made of silicon oxide (SiOx), silicon nitride (SiNx), or a multilayer thereof.

In addition, a gate electrode GE of the driving transistor DT can be disposed on the gate insulation layer 112. The gate electrode GE is disposed on the gate insulation layer 112 and overlaps the active layer ACT. The gate electrode GE can be made of various electrically conductive materials, for example, magnesium (Mg), aluminum (Al), nickel (Ni), chromium (Cr), molybdenum (Mo), tungsten (W), gold (Au), or an alloy thereof. However, the present disclosure is not limited thereto.

A first interlayer insulation layer 113a can be disposed to cover the gate electrode GE. A second interlayer insulation layer 113b can be disposed on the first interlayer insulation layer 113a.

A source electrode SE and a drain electrode DE of the driving transistor DT can be disposed on the second interlayer insulation layer 113b.

The source electrode SE and the drain electrode DE can be respectively connected to one side and the other side of the active layer ACT through contact holes provided in the second interlayer insulation layer 113b, the first interlayer insulation layer 113a, and the gate insulation layer 112. The source electrode SE and the drain electrode DE can each be made of various electrically conductive materials, for example, magnesium (Mg), aluminum (Al), nickel (Ni), chromium (Cr), molybdenum (Mo), tungsten (W), gold (Au), or an alloy thereof. However, the present disclosure is not limited thereto.

A portion of the active layer ACT, which overlaps the gate electrode GE, can be a channel area. One of the source electrode SE and the drain electrode DE is connected to one side of the channel area of the active layer ACT, and the other of the source electrode SE and the drain electrode DE is connected to the other side of the channel area of the active layer ACT.

A passivation layer 114 can be disposed on the source electrode SE and the drain electrode DE. The passivation layer 114 can serve to protect the driving transistor DT and be configured as an inorganic layer, for example, silicon oxide (Siox), silicon nitride (SiNx), or a multilayer thereof.

The planarization layer PLN can be positioned above the transistor layer TRL.

The planarization layer PLN can include a first planarization layer 115a and a second planarization layer 115b. The planarization layer PLN protects the driving transistor DT and planarizes the upper portion of the driving transistor DT.

The first planarization layer 115a can be disposed on the passivation layer 114.

A connection electrode CE can be disposed on the first planarization layer 115a.

The connection electrode CE can be connected to one of the source electrode SE and the drain electrode DE through a contact hole provided in the first planarization layer 115a.

The second planarization layer 115b can be disposed on the connection electrode CE.

The light-emitting element layer EDL can be positioned above the second planarization layer 115b.

Hereinafter, a layered structure of the light-emitting element layer EDL will be described in detail.

An anode E1 can be disposed on the second planarization layer 115b. In this case, the anode E1 can be electrically connected to the connection electrode CE through a contact hole provided in the second planarization layer 115b. The anode E1 can be made of a metallic material.

In case that the display device 100 is a top-emission type display device in which light emitted from the light-emitting element ED propagates toward an upper side of the substrate SUB on which the light-emitting element ED is disposed, the anode E1 can further include a transparent conductive layer and a reflective layer disposed below the transparent conductive layer. For example, the transparent conductive layer can be made of transparent conductive oxide such as ITO or IZO. For example, the reflective layer can be made of silver (Ag), aluminum (Al), gold (Au), molybdenum (Mo), tungsten (W), chromium (Cr), or an alloy thereof.

A bank 116 can be disposed to cover the anode E1. A portion of the bank 116, which corresponds to the light-emitting area of the subpixel, can be opened. A part of the anode E1 can be exposed through the opened portion (hereinafter, referred to as an open area) of the bank 116. In this case, the bank 116 can be made of an inorganic insulating material such as silicon nitride (SiNx) or silicon oxide (Siox), or an organic insulating material such as benzocyclobutene-based resin, acrylic resin, or imide-based resin. However, the present disclosure is not limited thereto.

A light-emitting layer EL can be disposed in the open area of the bank 116. Therefore, the light-emitting layer EL can be disposed on the anode E1 exposed through the open area of the bank 116.

A cathode E2 can be disposed on the light-emitting layer EL.

The light-emitting element ED can be formed by the anode E1, the light-emitting layer EL, and the cathode E2. The light-emitting layer EL can include a plurality of organic layers.

The encapsulation layer ENCAP can be positioned above the light-emitting element layer EDL.

The encapsulation layer ENCAP can have a single-layer or multilayer structure. For example, the encapsulation layer ENCAP can include a first encapsulation layer 117a, a second encapsulation layer 117b, and a third encapsulation layer 117c.

In this case, the first encapsulation layer 117a and the third encapsulation layer 117c can each be configured as an inorganic layer, and the second encapsulation layer 117b can each be configured as an organic layer. Among the first encapsulation layer 117a, the second encapsulation layer 117b, and the third encapsulation layer 117c, the second encapsulation layer 117b can be thickest and serve as a planarization layer.

The first encapsulation layer 117a can be disposed on the cathode E2 and closest to the light-emitting element ED. The first encapsulation layer 117a can be made of an inorganic insulating material that can be deposited at a low temperature.

For example, the first encapsulation layer 117a can be made of silicon nitride (SiNx), silicon oxide (Siox), silicon oxynitride (SiON), aluminum oxide (Al₂O₃), or the like. Because the first encapsulation layer 117a is deposited in a low-temperature ambience, it is possible to suppress damage to the light-emitting layer EL made of an organic material vulnerable to a high-temperature ambience during a deposition process.

The second encapsulation layer 117b can have a smaller area than the first encapsulation layer 117a. In this case, the second encapsulation layer 117b can be formed to expose two opposite ends of the first encapsulation layer 117a. The second encapsulation layer 117b can serve as a buffer for mitigating or addressing stress between the layers. The second encapsulation layer 117b can serve to improve the planarization performance.

For example, the second encapsulation layer 117b can be made of an organic insulating material such as acrylic resin, epoxy resin, polyimide, polyethylene, or silicon oxycarbon (SiOC). For example, the second encapsulation layer 117b can also be formed in an inkjet manner. However, the present disclosure is not limited thereto.

The third encapsulation layer 117c can be formed above the substrate SUB having the second encapsulation layer 117b to cover a top surface and a side surface of each of the second encapsulation layer 117b and the first encapsulation layer 117a. In this case, the third encapsulation layer 117c can minimize or block the penetration of outside moisture or oxygen into the first encapsulation layer 117a and the second encapsulation layer 117b. For example, the third encapsulation layer 117c can be made of an inorganic insulating material such as silicon nitride (SiNx), silicon oxide (Siox), silicon oxynitride (SiON), or aluminum oxide (Al₂O₃).

The touch sensing layer TSL can be disposed above the encapsulation layer ENCAP.

Specifically, the touch sensing layer TSL can include a touch buffer layer 118a disposed on the encapsulation layer ENCAP, a bridge electrode BE disposed on the touch buffer layer 118a, a touch interlayer insulation layer 118b disposed on the touch buffer layer 118a and the bridge electrode BE, and a touch electrode TE disposed on the touch interlayer insulation layer 118b.

The touch buffer layer 118a can inhibit outside moisture, foreign substances, or a liquid chemical such as a developer or an etching liquid, which is used during a process of manufacturing the touch electrodes formed on the touch buffer layer 118a, from penetrating into the light-emitting element.

The plurality of touch electrodes TE can include a plurality of first touch electrodes extending in a first direction, and a plurality of second touch electrodes extending in a second direction intersecting the first direction.

For example, the plurality of first touch electrodes and the plurality of second touch electrodes can be disposed on the same layer. However, the plurality of second touch electrodes can be disposed to be separated from one another in the area in which the plurality of first touch electrodes and the plurality of second touch electrodes intersect. The plurality of second touch electrodes, which are separated from one another, can be connected by the bridge electrodes BE. The touch interlayer insulation layers 118b can be disposed between the plurality of second touch electrodes and the bridge electrodes BE.

A protective layer PAC (119) can be disposed to cover the touch sensing layer TSL. The protective layer 119 can be configured as an organic insulation layer. The protective layer 119 can suppress a level difference on the uppermost layer of the display device 100, thereby improving the visibility of the display device 100.

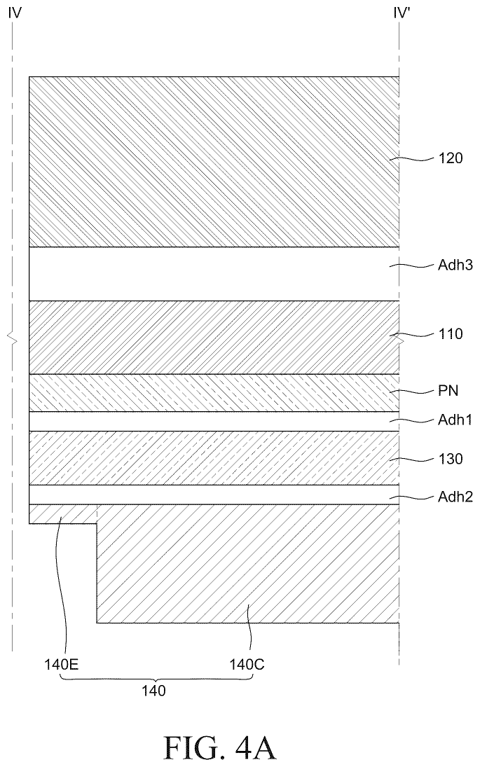

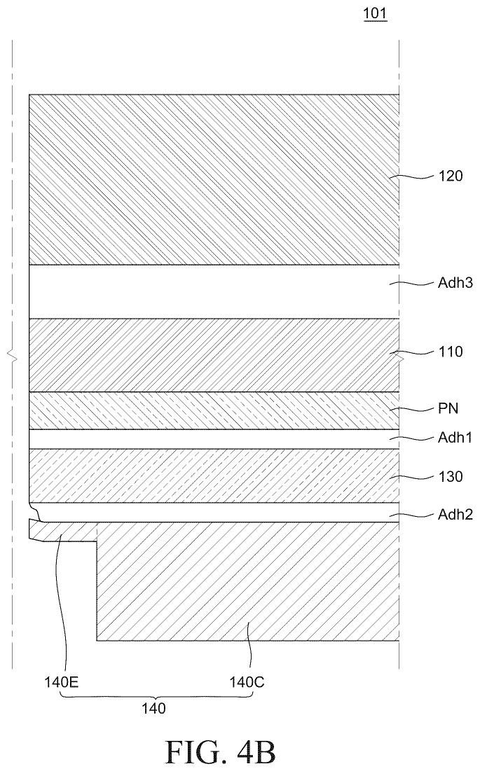

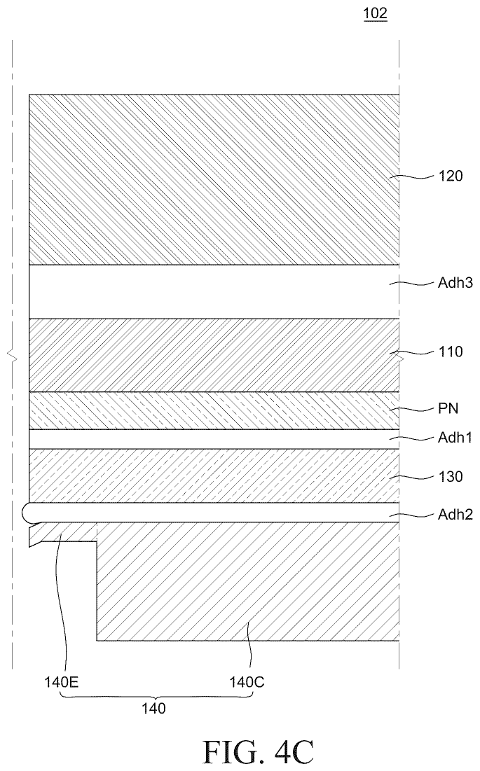

Hereinafter, an outer peripheral area of the display device 100 will be described in more detail with reference to FIGS. 4A, 4B, and 4C.

FIG. 4A is a cross-sectional view taken along line IV-IV′ in FIG. 1.

With reference to FIG. 4A, like the display area DA of the display device 100, the outer peripheral area of the display device 100 can include the cover member 120, the third bonding layer Adh3, the polarizing layer 110, the display panel PN, the first bonding layer Adh1, the backplate 130, the second bonding layer Adh2, and the metal plate 140.

After the display device 100 is manufactured, a reliability evaluation process, in which a high temperature and a low temperature are repeatedly provided, can be performed to identify stability of a product. There can be a problem in that the organic material is expanded at a high temperature and contracted at a low temperature during the reliability evaluation process.

With reference to FIGS. 2 and 3 together, the display device 100 is formed by stacking organic materials and inorganic materials, and a layer including the organic material has a larger thickness than a layer including the inorganic material.

For this reason, in the related art, there can be a problem in that stress can be generated by the contraction or expansion of the organic material during the reliability evaluation process. In particular, the expansion or contraction of the organic material can occur in the first or second bonding layer. In addition, the stress caused by the expansion or contraction of the organic material can be applied to the display panel including several layers and having a smaller thickness than the cover member, the backplate, or the metal plate, which can cause a problem in that the display panel has a defect, for example, the display panel cracks, and the transistor DT can be separated or deformed.

Therefore, in the display device according to the embodiment of the present disclosure, the position of the metal plate 140 varies, and for example, a central portion 140C of the metal plate 140 and an edge 140E of the metal plate 140 have different volumes, such that the stress, which can be caused by the contraction and expansion of the organic material, particularly, the second bonding layer Ahd2, is guided to the metal plate 140, and the stress to be applied to the display panel PN is mitigated or addressed, which can reduce or prevent a separation or deformation of the display panel PN. This configuration will be described in detail with reference to FIGS. 4B and 4C to be described below.

Specifically, in the display device according to the embodiment of the present disclosure, a thickness of the edge 140E of the metal plate 140 is smaller than a thickness of the central portion 140C of the metal plate 140, such that a volume of the edge 140E of the metal plate 140 can be smaller than a volume of the central portion 140C of the metal plate 140.

For example, the thickness of the edge 140E of the metal plate can be 50% or less of the thickness of the central portion 140C of the metal plate 140 or smaller than a thickness of the display panel PN. For example, the thickness of the edge 140E of the metal plate 140 can be determined on the basis of Equation 1 below. However, the present disclosure is not limited thereto.

$$[ Equation 1 ]$$

$$MP edge thickness = MP thickness \times \frac{1}{\frac{( TFT + BP ) yield strength \times ( TFT + BP ) thickness}{MP yield strength}}$$

In Equation 1, MP thickness represents the thickness of the edge 140E of the metal plate 140, MP thickness represents the thickness of the central portion 140C of the metal plate 140, MP yield strength represents yield strength of the metal plate 140, (TFT+BP) yield strength represents yield strength of the thin-film transistor DT and the backplate 130, and (TFT+BP) thickness represents a total sum of thicknesses of the thin-film transistor DT and the backplate 130.

FIG. 4B is a cross-sectional view of a display device according to another embodiment of the present disclosure.

The organic material can be contracted at a low temperature during the reliability evaluation process after a display device 101 is manufactured. For example, there occurs a problem in that the second bonding layer Adh2 is contracted during the reliability evaluation process. As in the related art, in case that an outer periphery of the display device has the same structure as the display area of the display device, the stress which can be caused by the contraction of the second bonding layer can be applied to an upper or lower portion of the second bonding layer. In this case, because the metal plate disposed below the second bonding layer has a larger thickness and higher rigidity than the constituent elements, i.e., the backplate, the first bonding layer, and the display panel positioned above the second bonding layer, the stress which can be caused by the contraction of the second bonding layer is difficult to apply. For this reason, the stress which can be caused by the contraction of the second bonding layer is applied to the constituent elements, i.e., the backplate, the first bonding layer, and the display panel positioned above the second bonding layer, which can cause a problem in that the constituent elements are deformed, e.g., warped in a direction in which the second bonding layer is disposed.

Therefore, in the display device according to another embodiment of the present disclosure, the thickness of the edge 140E of the metal plate 140 is smaller than the thickness of the central portion 140C of the metal plate 140 or a sum of thicknesses of the backplate 130, the first bonding layer Adh1, and the display panel PN, such that the stress which can be caused by the contraction of the second bonding layer Adh2 can be guided to the metal plate 140, specifically, the edge 140E of the metal plate 140 positioned below the second bonding layer Adh2 instead of being positioned above the second bonding layer Adh2.

In the display device according to another embodiment of the present disclosure, in case that the second bonding layer Adh2 is contracted, an end of a bottom surface of the second bonding layer Adh2 can be disposed inward of an end of a top surface of the second bonding layer Adh2, and the edge 140E of the metal plate 140 can have a shape curved in a direction in which the backplate 130 is disposed. In this case, a part of a top surface of the edge 140E of the metal plate 140 can be spaced apart from the second bonding layer Adh2.

As illustrated in FIG. 4B, in the display device 101 according to another embodiment of the present disclosure, the stress which can be caused by the contraction of the second bonding layer Adh2 is guided to the edge 140E of the metal plate 140 having a small thickness, such that stress to be applied to the display panel PN disposed above the second bonding layer Adh2 can be minimized or prevented, and a deformation of the display panel PN can be minimized or prevented.

In addition, in the display device 101 according to another embodiment of the present disclosure, the curved edge 140E of the metal plate 140 supports the second bonding layer Adh2 and supports the backplate 130, the first bonding layer Adh, and the display panel PN disposed above the second bonding layer Adh2, which can further suppress deformation of the display panel PN caused by the contraction of the second bonding layer Adh2.

FIG. 4C is a cross-sectional view of a display device according to still another embodiment of the present disclosure.

The organic material can be expanded at a high temperature during the reliability evaluation process after a display device 102 is manufactured. For example, there occurs a problem in that the second bonding layer Adh2 is expanded during the reliability evaluation process. As in the related art, in case that an outer periphery of the display device has the same structure as the display area of the display device, the stress which can be caused by the expansion of the second bonding layer can be applied to both the upper and lower portions of the second bonding layer. In this case, because the metal plate disposed below the second bonding layer has a thickness larger than a sum of thicknesses of the backplate, the first bonding layer, and the display panel and has rigidity, the stress which can be caused by the expansion of the second bonding layer is relatively difficult to apply in comparison with the backplate, the first bonding layer, and the display panel. For this reason, the stress which can be caused by the expansion of the second bonding layer is applied to the constituent elements, i.e., the backplate, the first bonding layer, and the display panel positioned above the second bonding layer, which can cause a problem in that the constituent elements are deformed, e.g., warped in a direction in which the backplate, the display panel, and the cover member are disposed.

In the display device according to yet another embodiment of the present disclosure, the thickness of the edge 140E of the metal plate 140 is smaller than the thickness of the central portion 140C of the metal plate 140 or a sum of thicknesses of the backplate 130, the first bonding layer Adh, and the display panel PN, such that the stress which can be caused by the expansion of the second bonding layer Adh2 can be guided to the metal plate 140, specifically, the edge 140E of the metal plate 140 positioned below the second bonding layer Adh2 instead of being positioned above the second bonding layer Adh2.

In the display device according to still another embodiment of the present disclosure, in case that the second bonding layer Adh2 is expanded, one end of the second bonding layer Adh2 can further protrude than one end of the edge 140E of the metal plate 140, and the edge 140E of the metal plate can have a shape curved in a downward direction. In this case, a part of a top surface of the edge 140E of the metal plate 140 can be spaced apart from the second bonding layer Adh2.

As illustrated in FIG. 4C, the stress which can be caused by the expansion of the second bonding layer Adh2 is guided to the edge 140E of the metal plate 140 having a small thickness, such that stress to be applied to the backplate 130, the first bonding layer Adh, and the display panel PN disposed above the second bonding layer Adh2 can be minimized or addressed, and deformation of the display panel PN can be minimized or addressed.

In addition, in the related art, the stress which can be caused by the expansion of the second bonding layer can be applied to both the upper and lower portions of the second bonding layer.

In contrast, in the display device 102 according to still another embodiment of the present disclosure, the overall stress which can occur on the second bonding layer Ahd2 is guided to the edge 140E of the metal plate 140 that can transmit the stress. Therefore, because the stress is not guided to the upper portion of the second bonding layer Ahd2, it is possible to suppress or prevent the deformation of the display panel PN caused by the expansion of the second bonding layer Adh2.

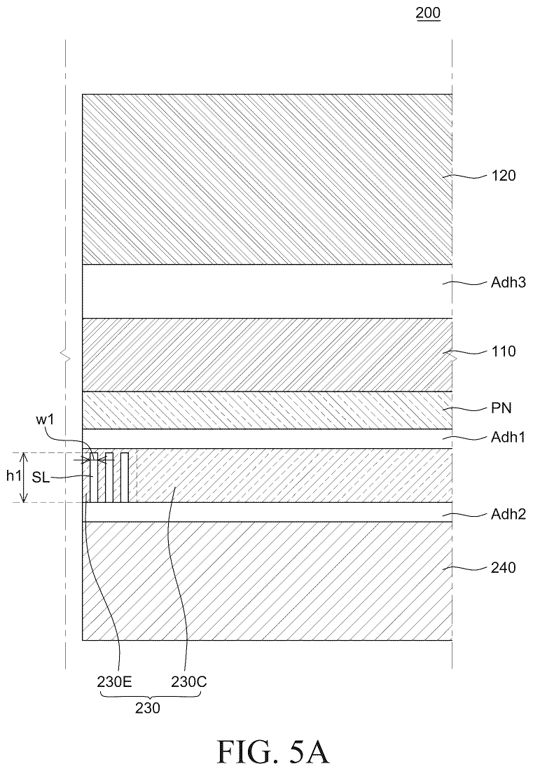

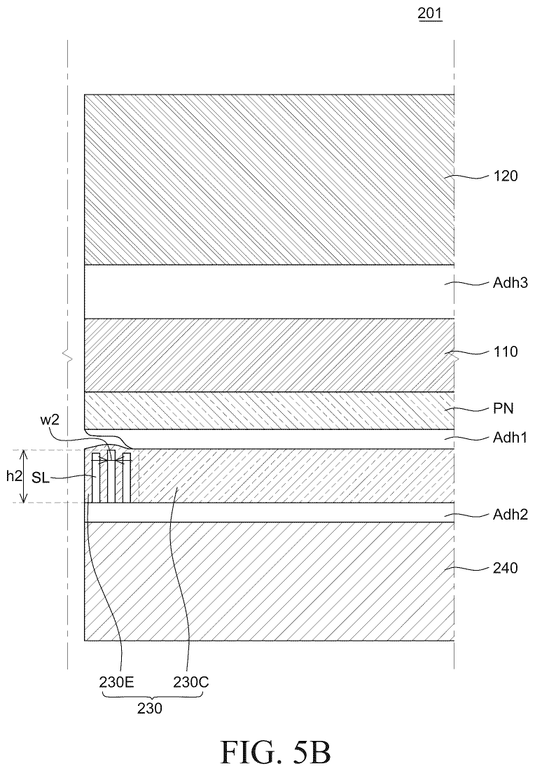

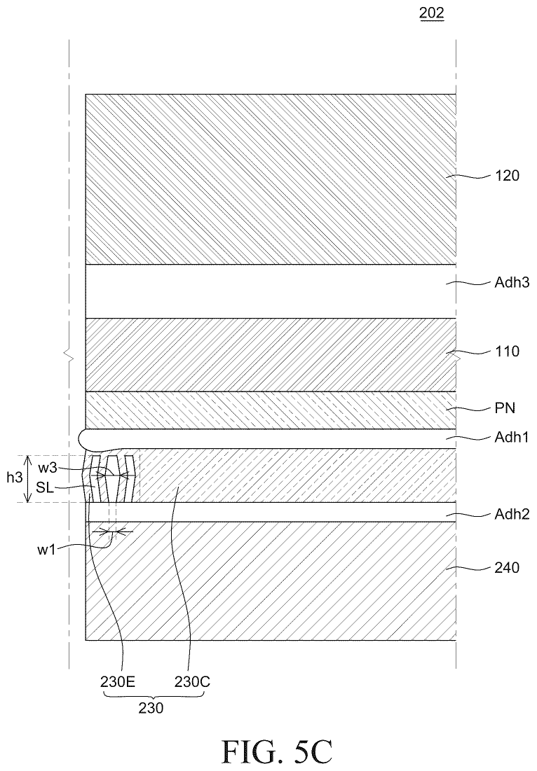

Hereinafter, an outer peripheral area of a display device according to yet another embodiment of the present disclosure will be described in more detail with reference to FIGS. 5A, 5B, and 5C together.

FIG. 5A is a cross-sectional view of a non-display area of a display device according to yet another embodiment of the present disclosure. A display device in FIG. 5A is substantially identical in configuration to the display device in FIGS. 1 to 4A, except for a backplate 230 and a metal plate 240. Therefore, repeated descriptions of the identical components will be omitted or may be briefly provided. The same reference numerals are used for the same components. Hereinafter, the components denoted by the same reference numerals can be understood by referring to the descriptions provided herein in association with FIGS. 1 to 4A.

With reference to FIG. 5A, like the display area DA illustrated in FIGS. 2 and 3, an outer peripheral area of a display device 200 can include the cover member 120, the third bonding layer Adh3, the polarizing layer 110, the display panel PN, the first bonding layer Adh1, the backplate 230, the second bonding layer Adh2, and the metal plate 240.

The backplate 230 disposed below the display panel PN can support the display panel PN and protect the display panel PN from external moisture, heat, impact, or the like. The backplate 230 can be made of a transparent organic insulating material to suppress curl and static electricity of the display device 200 and inspect an external appearance of the rear surface of the display device 200. For example, the backplate 130 can be made of a plastic material such as polymethyl methacrylate (PMMA), polycarbonate (PC), polyvinyl alcohol (PVA), acrylonitrile-butadiene-styrene (ABS), polyethylene terephthalate (PET), silicone, and polyurethane (PU). However, the present disclosure is not limited thereto.

The metal plate 240 can be disposed below the backplate 230. In the display device according to yet another embodiment of the present disclosure, the metal plate 240 disposed below the backplate 230 can have the same thickness or the same volume. For example, the metal plate 240 can protect the backplate 230 from an external impact that can be applied during the process of manufacturing the display device. In addition, the metal plate 240 can serve as a heat dissipation plate for dissipating heat, which is generated from the display panel PN, to the outside. The metal plate 240 can be made of a metallic material such as stainless steel (SUS), stainless steel (SUS) containing different metals such as nickel (Ni), iron (Fe), aluminum (Al), and magnesium (Mg). Particularly, stainless steel (SUS) can be applied to the metal plate 240. For example, because stainless steel (SUS) has high restoring force and rigidity, the metal plate 240 can maintain high rigidity even though a thickness of the metal plate 240 decreases.

After the display device 200 is manufactured, a reliability evaluation process, in which a high temperature and a low temperature are repeatedly provided, can be performed to identify stability of a product. There is a problem in that the organic material is expanded at a high temperature and contracted at a low temperature during the reliability evaluation process. With reference to FIGS. 2 and 3 together, the display device 100 is formed by stacking organic materials and inorganic materials, and a layer including the organic material has a larger thickness than a layer including the inorganic material. For this reason, in the related art, there can be a problem in that stress is generated by the contraction or expansion of the organic material during the reliability evaluation process. In particular, the expansion or contraction of the organic material can occur in the first or second bonding layer. In addition, the stress which can be caused by the expansion or contraction of the organic material is applied to the display panel PN including several layers and having a smaller thickness than the cover member, the backplate, or the metal plate, which can cause a problem in that the display panel PN has a defect, for example, the display panel PN cracks, and the transistor DT can be separated or deformed.

Therefore, in the display device according to yet another embodiment of the present disclosure, the position of the backplate 230 varies, and for example, a central portion 230C of the backplate and an edge 230E of the backplate have different volumes, such that the stress, which can be caused by the contraction and expansion of the organic material, particularly, the first bonding layer Adh1, is guided to the backplate 230, and the stress to be applied to the display panel PN is mitigated, which can reduce or prevent a separation or deformation of the display panel PN. This configuration will be described in detail with reference to FIGS. 5B and 5C to be described below.

Specifically, in the display device according to yet another embodiment of the present disclosure, the edge 230E of the backplate includes at least one slit pattern SL, such that a volume of the edge 230E of the backplate can be smaller than a volume of the central portion 230C of the backplate.

For example, at least one slit pattern SL can be disposed to surround the display area DA.

At least one slit pattern SL can have a shape made by perforating a part of the backplate 230. For example, a bottom surface of the backplate 230 corresponding to at least one slit pattern SL of the edge 230E of the backplate can be perforated. However, the present disclosure is not limited thereto. For example, the bottom surface of the backplate 230 corresponding to at least one slit pattern SL of the edge 230E of the backplate may not be perforated. For example, a slit pattern SL (opening pattern) having a closed shape can be disposed on a central portion of the backplate corresponding to at least one slit pattern SL of the edge 230E of the backplate.

At least one slit pattern SL has a first width w1 and a first length h1. The slit patterns SL can be spaced apart from one another in a first direction (x-axis direction). In this case, a length of at least one slit pattern SL can be smaller than a thickness of the backplate 230.

For example, a volume of the edge 230E of the backplate including at least one slit pattern SL can be determined on the basis of Equation 2 below. However, the present disclosure is not limited thereto.

$$[ Equation 2 ]$$

$$BP edge Volume = ( MP + BP ) Volume \times \frac{1}{\frac{TFT yield strength \times TFT Volume}{( MP + BP ) yield strength}}$$

In Equation 2, BP edge Volume represents a volume of the edge 230E of the backplate, (MP+BP) Volume represents a sum of volumes of the metal plate 240 and the central portion 230C of the backplate, (MP+BP) yield strength represents a sum of yield strength of the metal plate 240 and yield strength of the backplate 230, TFT yield strength represents yield strength of the thin-film transistor DT, and TFT volume represents a volume of the thin-film transistor DT.

FIG. 5B is a cross-sectional view of a non-display area of a display device according to still yet another embodiment of the present disclosure.

The organic material can be contracted at a low temperature during the reliability evaluation process after a display device 201 is manufactured. For example, there occurs a problem in that the first bonding layer Adh1 is contracted during the reliability evaluation process. As in the related art, in case that an outer periphery of the display device has the same structure as the display area of the display device, the stress which can be caused by the contraction of the first bonding layer can be applied to an upper or lower portion of the first bonding layer. In this case, because the backplate disposed below the first bonding layer has a larger thickness than the display panel, the stress which can be caused by the contraction of the first bonding layer is relatively difficult to apply in comparison with the display panel. For this reason, the stress which can be caused by the contraction of the first bonding layer is applied to the display panel, i.e., the constituent element positioned above the first bonding layer, which can cause a problem in that the constituent elements are deformed, e.g., warped in a direction in which the first bonding layer is disposed.

Therefore, in the display device according to still yet another embodiment of the present disclosure, the edge 230E of the backplate includes at least one slit pattern SL, such that the stress which can be caused by the contraction of the first bonding layer Adh1 can be guided to the backplate 230, specifically, the edge 230E of the backplate positioned below the first bonding layer Adh1 instead of being positioned above the first bonding layer Adh1.

In the display device according to still yet another embodiment of the present disclosure, in case that the first bonding layer Adh1 is contracted, an end of the bottom surface of the first bonding layer Adh1 can be disposed inward of an end of the top surface of the first bonding layer Adh1, at least one slit pattern SL can have a second width w2 smaller than the first width w1 and have a second length h2 larger than the first length h1, and a part of the top surface of the edge 230E of the backplate can have a shape protruding in a direction in which the display panel PN is disposed. In this case, a part of the top surface of the edge 230E of the backplate can be spaced apart from the first bonding layer Adh1.

As illustrated in FIG. 5B, in the display device 201 according to still yet another embodiment of the present disclosure, the backplate 230 is made of a plastic material having flexibility, such that the backplate 230 can also be deformed if the stress which can be caused by the contraction of the first bonding layer Adh1 is applied.

Specifically, in the display device 201 according to still yet another embodiment of the present disclosure, at least one slit pattern SL is disposed at the edge 230E of the backplate, such that the edge 230E of the backplate having at least one slit pattern SL can be deformed in case that a force is applied to the backplate 230.

For example, in the display device according to still yet another embodiment of the present disclosure, when the first bonding layer Adh1 is contracted, the edge 230E of the backplate can be deformed in shape by at least one slit pattern SL made by perforating a part of the backplate 230 at the edge 230E of the backplate.

As illustrated in FIG. 5B, in the display device 201 according to still yet another embodiment of the present disclosure, the stress which can be caused by the contraction of the first bonding layer Adh1 is guided to the edge 230E of the backplate having a small volume, such that stress to be applied to the display panel PN disposed above the first bonding layer Adh1 can be minimized or prevented, and a deformation of the display panel PN can be minimized or prevented.

In addition, in the display device 201 according to still yet another embodiment of the present disclosure, the curved edge 230E of the backplate supports the first bonding layer Adh1 and supports the display panel PN disposed above the first bonding layer Adh1, which can further suppress deformation of the display panel PN caused by the contraction of the first bonding layer Adh1.

FIG. 5C is a cross-sectional view of a non-display area of a display device according to a further embodiment of the present disclosure.

The organic material can be expanded at a high temperature during the reliability evaluation process after a display device 202 is manufactured. For example, there occurs a problem in that the first bonding layer Adh1 is expanded during the reliability evaluation process. As in the related art, in case that an outer periphery of the display device has the same structure as the display area of the display device, the stress which can be caused by the expansion of the first bonding layer can be applied to both the upper and lower portions of the first bonding layer. In this case, because the backplate disposed below the first bonding layer has a larger thickness than the display panel, the stress which can be caused by the expansion of the first bonding layer is relatively difficult to apply in comparison with the display panel. For this reason, the stress which can be caused by the expansion of the first bonding layer is applied to the display panel, i.e., the constituent element positioned above the first bonding layer, which can cause a problem in that the constituent elements are deformed, e.g., warped in a direction in which the cover member of the display panel is disposed.

In the display device according to another embodiment of the present disclosure, the edge 230E of the backplate includes at least one slit pattern SL, such that the stress which can be caused by the expansion of the first bonding layer Adh1 can be guided to the backplate 230, specifically, the edge 230E of the backplate positioned below the first bonding layer Adh1 instead of being positioned above the first bonding layer Adh1.

In the display device according to another embodiment of the present disclosure, in case that the first bonding layer Adh1 is expanded, one end of the first bonding layer Adh1 can further protrude than one end of the display panel PN, two opposite ends of at least one slit pattern SL can have the first width w1, a central portion of at least one slit pattern SL can have a third width w3 larger than the first width w1, and a length of at least one slit pattern SL can be a third length h3 shorter than the first length h1. For example, when the first bonding layer Adh1 is expanded in case that at least one slit pattern SL is provided as at least two slit patterns SL, the two opposite ends of the slit pattern SL positioned inward can have the first width w1, the central portion of at least one slit pattern SL can have the third width w3 larger than the first width w1, the length of at least one slit pattern SL can be the third length h3 shorter than the first length h1, and the slit pattern SL positioned at the outer periphery can be deformed together with the deformation of the slit pattern SL positioned inward. For example, the slit pattern SL positioned at the outer periphery can have the first width w1 and the first length h1 and be warped in accordance with the deformation of the slit pattern SL positioned inward.

As illustrated in FIG. 5C, the stress which can be caused by the expansion of the first bonding layer Adh1 is guided to the edge 230E of the backplate that is easily deformed, such that stress to be applied to the display panel PN disposed above the first bonding layer Adh1 can be minimized or eliminated, and the deformation of the display panel PN can be minimized or eliminated.

In addition, in the related art, the stress which can be caused by the expansion of the first bonding layer is applied to both the upper and lower portions of the first bonding layer.

In contrast, in the display device 202 according to another embodiment of the present disclosure, the overall stress which can occur on the first bonding layer Ahd1 is guided to the edge 230E of the backplate that is easily deformed. Therefore, because the stress is not guided to the upper portion of the first bonding layer Ahd1, it is possible to suppress or prevent the deformation of the display panel PN which can be caused by the expansion of the first bonding layer Adh1.

The edge 140E of the metal plate 140 or the edge 230E of the backplate 230 according to another embodiment of the present disclosure can be disposed at the outer periphery of the non-display area NDA that surrounds the display area DA.

In addition, the edge 140E of the metal plate 140 or the edge 230E of the backplate 230 according to another embodiment of the present disclosure can be disposed to surround the through-hole TH.

For example, in the display device according to another embodiment of the present disclosure, the edge 140E of the metal plate 140 or the edge 230E of the backplate 230, which surrounds the outer periphery of the display device 100 or 200 or surrounds the outer periphery of the optical area OA in which the through-hole TH is disposed, can be deformed in shape. Therefore, even though the organic material, i.e., the first bonding layer Adh1 or the second bonding layer Adh2 is contracted or expanded during the process of evaluating the reliability of the display device 100 or 200, stress to be applied to the display panel PN can be minimized, and deformation of the display panel PN can be minimized.

The example embodiments of the present disclosure can also be described as follows:

According to an aspect of the present disclosure, a display device includes a display panel including a display area and a non-display area configured to surround the display area, a backplate disposed below the display panel, a first bonding layer disposed between the display panel and the backplate, a metal plate disposed on a rear surface of the backplate, and a second bonding layer disposed between the backplate and the metal plate, an edge of the backplate or an edge of the metal plate has a smaller volume than a central portion of the backplate or a central portion of the metal plate.

A thickness of the edge of the metal plate can be smaller than a thickness of a central portion of the metal plate.

An end of a bottom surface of the second bonding layer is disposed inward of an end of a top surface of the second bonding layer, and the edge of the metal plate can have a shape curved in a direction in which the backplate is disposed.

A part of a top surface of the edge of the metal plate can be spaced apart from the second bonding layer.

One end of the second bonding layer further protrudes than one end of the edge of the metal plate, and the edge of the metal plate can have a shape curved in a downward direction.

A part of a top surface of the edge of the metal plate can be spaced apart from the second bonding layer.

The edge of the backplate can include at least one slit pattern.

The at least one slit pattern can be disposed to surround the display area.

The at least one slit pattern has a first width and a first length, and the first length can be smaller than a thickness of the backplate.

The backplate can include a plastic material.

An end of a bottom surface of the first bonding layer is disposed inward of an end of a top surface of the first bonding layer, the at least one slit pattern has a shape having a second width smaller than the first width and having a second length longer than the first length, and a part of a top surface of the edge of the backplate can protrude in a direction in which the display panel is disposed.

A part of a top surface of the edge of the backplate can be spaced apart from the first bonding layer.

One end of the first bonding layer further protrudes than one end of the display panel, two opposite ends of the at least one slit pattern have the first width, a central portion of the at least one slit pattern has a third width larger than the first width, and the at least one slit pattern can have a shape having a third length shorter than the first length.

The edge of the backplate or the edge of the metal plate can be disposed at an outer periphery of the non-display area that surrounds the display area.

The display device can further include an optical area disposed in the display area and including a through-hole, the edge of the backplate or the edge of the metal plate can be disposed to surround the through-hole.

The display device can further include an electronic optical device disposed to overlap the optical area.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device comprising:
a display panel including a display area and a non-display area configured to surround at least a part of the display area;
a backplate disposed below the display panel;
a first bonding layer disposed between the display panel and the backplate;
a metal plate disposed on a rear surface of the backplate; and
a second bonding layer disposed between the backplate and the metal plate,
wherein an edge of the backplate or an edge of the metal plate has a smaller volume than a central portion of the backplate or a central portion of the metal plate.

2. The display device of claim 1, wherein a thickness of the edge of the metal plate is smaller than a thickness of the central portion of the metal plate.

3. The display device of claim 2, wherein an end of a bottom surface of the second bonding layer is disposed inward of an end of a top surface of the second bonding layer, and the edge of the metal plate has a shape curved in a direction in which the backplate is disposed.

4. The display device of claim 3, wherein a part of a top surface of the edge of the metal plate is spaced apart from the second bonding layer.

5. The display device of claim 2, wherein one end of the second bonding layer protrudes further than one end of the edge of the metal plate, and the edge of the metal plate has a shape curved in a downward direction.

6. The display device of claim 5, wherein a part of a top surface of the edge of the metal plate is spaced apart from the second bonding layer.

7. The display device of claim 1, wherein the edge of the backplate includes at least one slit pattern.

8. The display device of claim 7, wherein the at least one slit pattern is disposed to surround the display area.

9. The display device of claim 8, wherein the at least one slit pattern has a first width and a first length, and the first length is smaller than a thickness of the backplate.

10. The display device of claim 9, wherein the backplate includes a plastic material.

11. The display device of claim 10, wherein an end of a bottom surface of the first bonding layer is disposed inward of an end of a top surface of the first bonding layer,
the at least one slit pattern has a shape having a second width smaller than the first width and having a second length longer than the first length, and
a part of a top surface of the edge of the backplate protrudes in a direction in which the display panel is disposed.

12. The display device of claim 11, wherein a part of the top surface of the edge of the backplate is spaced apart from the first bonding layer.

13. The display device of claim 10, wherein one end of the first bonding layer protrudes further than one end of the display panel,
two opposite ends of the at least one slit pattern have the first width,
a central portion of the at least one slit pattern has a third width larger than the first width, and
the at least one slit pattern has a shape with a third length shorter than the first length.

14. The display device of claim 1, wherein the edge of the backplate or the edge of the metal plate is disposed at an outer periphery of the non-display area that surrounds the display area.

15. The display device of claim 1, further comprising:
an optical area disposed in the display area and including a through-hole,
wherein the edge of the backplate or the edge of the metal plate is disposed to surround the through-hole of the optical area.

16. The display device of claim 15, further comprising:
an electronic optical device disposed to overlap with the optical area.
